(19) United States
(12) Patent Application Publication
(10) Pub. No.: US 2012/0224304 A1
(43) Pub. Date: Sep. 6, 2012

(54) REPLACEABLE ASSEMBLING ELEMENT FOR FIXING STRUCTURES AND ASSEMBLING METHOD FOR STRUCTURE COMPONENTS OF ELECTRONIC DEVICE

(75) Inventor: Chun-Hsien Huang, Taipei City (TW)

(73) Assignee: COMPAL ELECTRONICS, INC., Taipei City (TW)

(21) Appl. No.: 13/327,728

(22) Filed: Dec. 15, 2011

Related U.S. Application Data
(60) Provisional application No. 61/448,175, filed on Mar. 1, 2011.

(51) Int. Cl. H05K 7/00; B32B 37/12; H05K 13/04; B23P 11/00; B23P 17/00

(52) U.S. Cl. 361/679.01; 29/428; 29/402.08; 29/525.01; 156/91

(57) ABSTRACT

A replaceable assembling element for fixing structures is suitable for an electronic device. The electronic device has a first structure component and a second structure component. The assembling element includes a main part and a hook part. The main part is fixed at the first structure component, the hook part is connected to the main part and buckled to the second structure component so as to lock the first structure component to the second structure component firmly. In addition, an assembling method for structure components of an electronic device is also involved.

### CROSS-REFERENCE TO RELATED APPLICATION

This application claims the priority benefits of U.S. provisional application Ser. No. 61/448,175, filed on Mar. 1, 2011. The entirety of the above-mentioned patent application is hereby incorporated by reference herein and made a part of this specification.

### BACKGROUND OF THE INVENTION

1. Field of the Invention

The invention generally relates to an assembling element, and more particularly, to a replaceable assembling element for fixing structure components suitable for an electronic device.

2. Description of Related Art

The notebook computer has the same function as the desktop computer, but it has a slim design suitable for a user to carry it portably. Therefore, the notebook computer has become an indispensable on-the-go tool for many users. With the steady drop on its price, some users even directly replace the desktop computer with the notebook computer.

Generally, a bottom cover of the host of a notebook computer is fixed with screws. Thus, a user needs to remove many screws to detach the bottom cover, which makes maintaining and disassembling the host inconvenient. In addition, screws exposing out of the bottom cover would affect the artistic appearance the notebook computer.

### SUMMARY OF THE INVENTION

Accordingly, the present invention is directed to a replaceable assembling element for fixing structures, which enables the structure components of an electronic device to be assembled and disassembled conveniently.

The present invention is also directed to an assembling method for structure components of an electronic device. Accordingly, the structure components of an electronic device can be assembled and dissembled conveniently.

The present invention provides a replaceable assembling element for fixing structure components suitable for an electronic device. The electronic device has a first structure component and a second structure component. The assembling element includes a main part and a hook part. The main part is fixed to the first structure component, the hook part is connected to the main part and buckled to the second structure component so as to lock the first structure component to the second structure component firmly.

In an embodiment of the present invention, the above-mentioned main part has a fastening hole, the electronic device further has a fastening element and the fastening element fastens the main part to the first structure component through the fastening hole.

In an embodiment of the present invention, the above-mentioned hook part is integrally connected to the main part.

In an embodiment of the present invention, the above-mentioned main part has a recess, the electronic device further has a bump and the bump is fixed to the first structure component and inserted into the recess of the main part.

In an embodiment of the present invention, the above-mentioned main part has a first fastening hole and the bump has a second fastening hole, the electronic device further has a fastening element and the fastening element fastens the main part to the first structure component through the first fastening hole and the second fastening hole.

In an embodiment of the present invention, the above-mentioned main part is glued to the first structure component.

In an embodiment of the present invention, the above-mentioned assembling element is fixed to an inner surface of the first structure component and hidden in the electronic device.

In an embodiment of the present invention, the above-mentioned assembling element is made of plastic.

The invention also provides an assembling method suitable for an electronic device, in which the electronic device has a first structure component and a second structure component. The assembling method includes: providing an assembling element, in which the assembling element includes a main part and a hook part, and the hook part is connected to the main part; fixing the main part to the first structure component; applying an external force onto the first structure component or the second structure component so as to lock the hook part of the first structure component to the second structure component firmly.

In an embodiment of the present invention, the above-mentioned assembling method further includes a step of detaching the buckled first structure component from the second structure component, in which the detaching method includes: applying an external force onto one of the first structure component and the second structure component so as to break the hook part of the assembling element to separate the buckled first structure component from the second structure component; removing the damaged assembling element and installing another assembling element.

In an embodiment of the present invention, the above-mentioned main part has a fastening hole and the step of fixing the main part to the first structure component includes: providing a fastening element; and fastening, by the fastening element, the main part to the first structure component through the fastening hole.

In an embodiment of the present invention, the above-mentioned main part has a recess, the electronic device has a bump, the bump is fixed at the first structure component, and the step of fixing the main part to the first structure component includes: inserting the bump into the recess of the main part.

In an embodiment of the present invention, the above-mentioned main part has a first fastening hole, the bump has a second fastening hole, and the step of fixing the main part to the first structure component includes: providing a fastening element; and fastening, by the fastening element, the main part to the first structure component through the first fastening hole and the second fastening hole.

In an embodiment of the present invention, the above-mentioned step of fixing the main part to the first structure component includes: gluing the main part to the first structure component.

In an embodiment of the present invention, the aforementioned method of fastening the first structure component to the second structure component is screwless buckling.

Based on the above description, the assembling element of the invention is fixed to the first structure component so that the first structure component can be locked to the second structure component firmly through the hook part of the main part. Accordingly, the first structure component can be assembled with the second structure component without screws. Therefore, users are enabled to quickly assemble or dissemble the first structure component, and thus electronic devices can be maintained and dissembled more conveniently.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the present invention and, together with the description, serve to explain the principles of the present invention.

FIG. 1 is a 3-dimensional diagram of an assembling element according to an embodiment of the present invention.

FIG. 2 is a cross-sectional diagram of the assembling element of FIG. 1 used in an electronic device.

FIG. 3 is a 3-dimensional diagram of partial parts of the electronic device of FIG. 2.

FIG. 4 is a 3-dimensional diagram of the first structure component and the assembling element of FIG. 1.

FIG. 5 is a flowchart of an assembling method of the structure components of the electronic device in FIG. 1.

### DESCRIPTION OF THE EMBODIMENTS

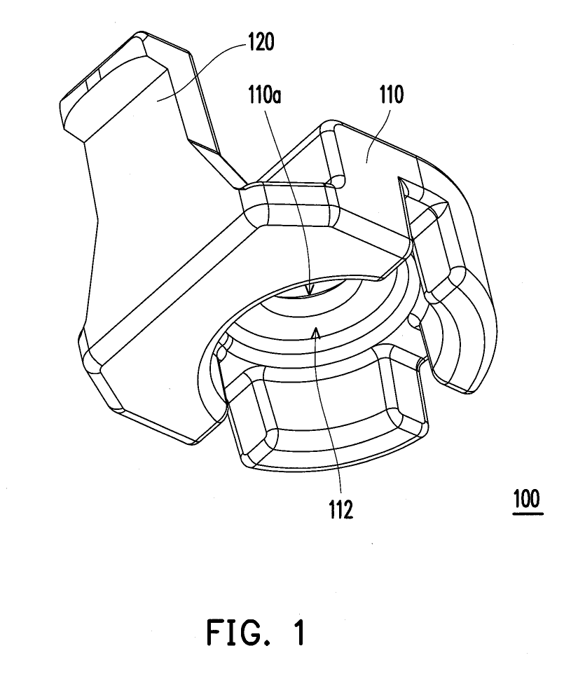

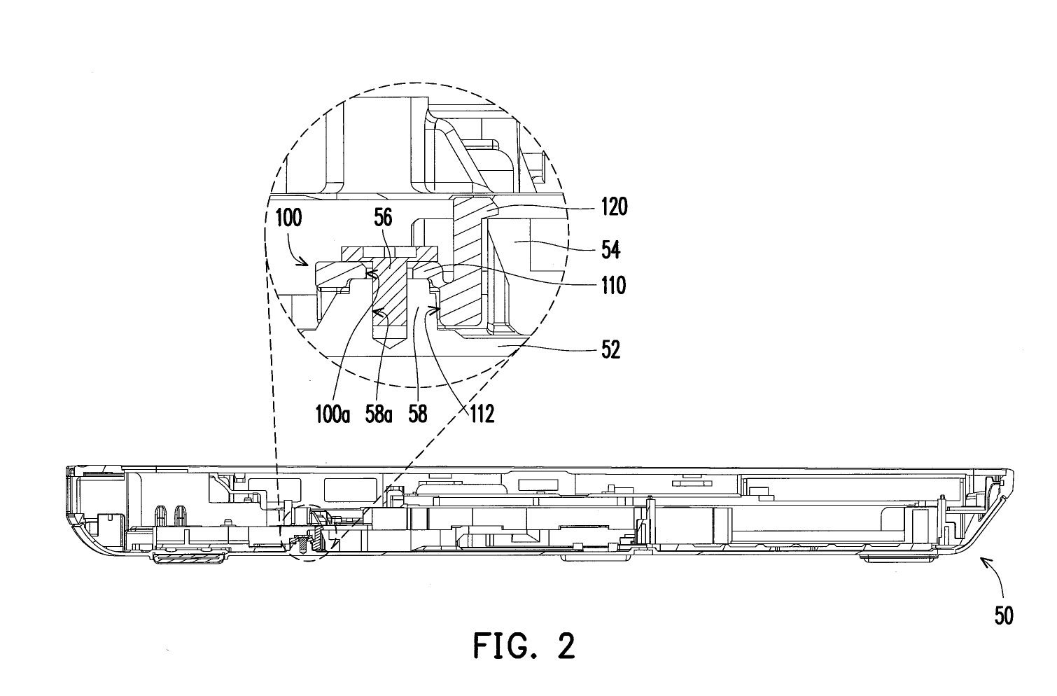

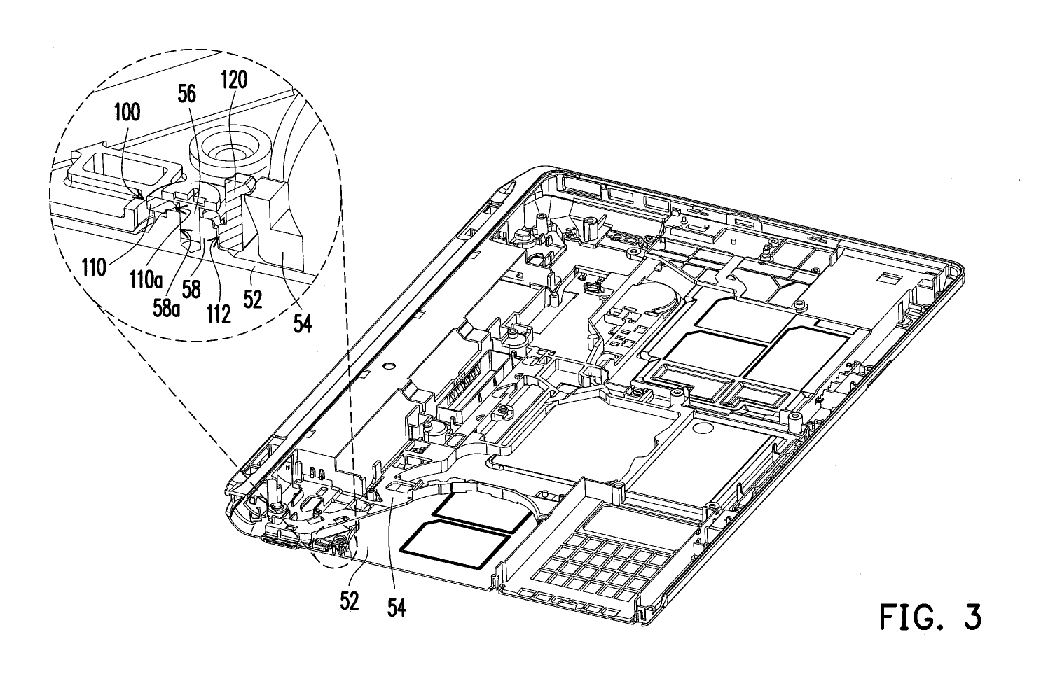

FIG. 1 is a 3-dimensional diagram of an assembling element according to an embodiment of the present invention, FIG. 2 is a cross-sectional diagram of the assembling element of FIG. 1 used in an electronic device, and FIG. 3 is a 3-dimensional diagram of partial parts of the electronic device of FIG. 2. Referring to FIGS. 1-3, an assembling element 100 of the embodiment is suitable for an electronic device 50, and the electronic device 50 is, for example, a notebook computer's host and has a first structure component 52 and a second structure component 54. The assembling element 100 includes a main part 110 and a hook part 120. The main part 110 is fixed to the first structure component 52, while the hook part 120 is integrally connected to the main part 110 and buckled to the second structure component 54 so as to lock the first structure component 52 to the second structure component 54 firmly.

With the above-mentioned configuration, the first structure component 52 can be locked to the second structure component 54 firmly through the hook part 120 of the assembling element 100. As a result, the first structure component 52 can be assembled to the second structure component 54 without screws. Therefore, users are enabled to quickly assemble or dissemble the first structure component 52, and thus the electronic devices 50 can be maintained and dissembled more conveniently.

In the embodiment, the materials of the first structure component 52 and the second structure component 54 are metallic material being lighter and having better structural strength, such as aluminium, magnesium, and so on. The material of the assembling element 100 is, for example, plastic so that it is easier to assemble or disassemble the first structure component 52 and the second structure component 54 by elastic deformation of the hook part 120. In other embodiments, the material of the first structure component 52, the second structure component 54 and the assembling element 100 may be other appropriate materials, which is not limited in the present invention.

In the embodiment, the main part 110 of the assembling element 100 has a fastening hole 110a and the electronic device 50 further has a fastening element 56. The fastening element 56 fastens the main part 110 onto the first structure component 52 through the fastening hole 110a. In addition, the main part 110 of the assembling element 100 has a recess 112 and the electronic device 50 further has a bump 58. The bump 58 is fixed to the first structure component 52 and inserted into the recess 112 so as to further fix the main part 110 and avoid the main part 110 from moving comparatively to the first structure component 52. The bump 58 of the embodiment is, for example, integrally connected to the first structure component 52. In the embodiment, the bump 58 has a fastening hole 58a, and the fastening element 56 goes through the fastening hole 110a to be fastened into the fastening hole 58a and to fasten the main part 110 onto the first structure component 52. In other embodiments, the main part 110 of the assembling element 100 can be fixed at the first structure component 52 in a gluing way, and the fixing method is not limited herein.

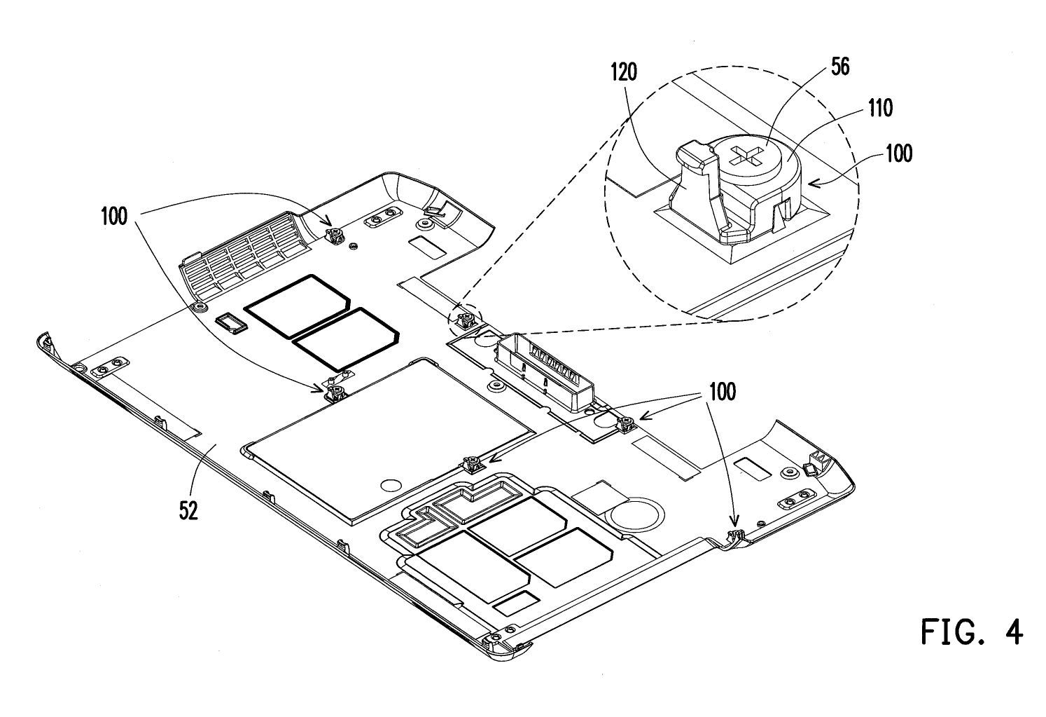

FIG. 4 is a 3-dimensional diagram of the first structure component and the assembling element of FIG. 1. Referring to FIG. 4, the number of the assembling elements 100 in the embodiment is, for example, six, so that the first structure component 52 can be firmly assembled to the second structure component 54. In other embodiments, the number of the assembling elements 100 may vary appropriately, which is not limited in the present invention. In addition, as shown by FIGS. 2 and 3, the assembling element 100 of the embodiment is fixed to an inner surface of the first structure component 52 and hidden within the electronic device 50 so as to provide better appearance for the electronic device 50.

In the following examples, an assembling method of using the assembling elements of the present invention is disclosed, with reference to the electronic device 50 and the assembling element 100 of FIGS. 1-4.

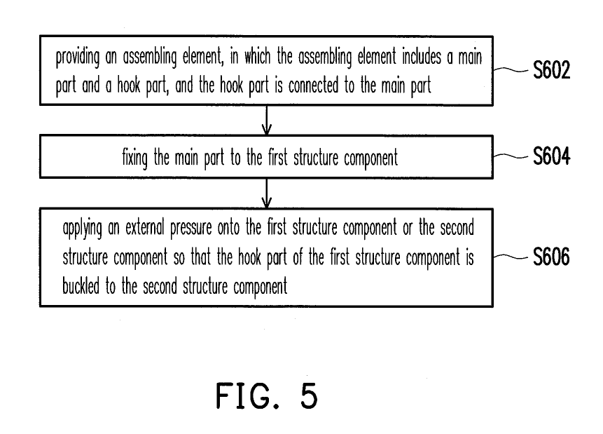

FIG. 5 is a flowchart of an assembling method of the structure components of the electronic device in FIG. 1. Referring to FIG. 5, an assembling element 100 is provided as shown in FIG. 1. The assembling element 100 includes a main part 110 and a hook part 120 and the hook part 120 is connected to the main part 110 (step S602). Next, the main part 110 is fixed to the first structure component 52 as shown in FIG. 4 (step S604). Finally, as shown in FIGS. 2 and 3, an external force is applied onto the first structure component 52 or the second structure component 54 so that the hook part 120 of the first structure component 52 is buckled to the second structure component 54 (step S606). Specifically, in step S606, the first structure component 52 is buckled with the second structure component 54 without screws so as to achieve the purpose of convenient assembly.

In the above-mentioned step S604, the step of fixing the main part 110 to the first structure component 52 includes inserting the bump 58 fixed to the first structure component 52 into the recess 112 of the main part 110. In addition, in step S604, the step of fixing the main part 110 to the first structure component 52 further includes providing a fastening element 56, which fastens the main part 110 to the first structure component 52 through the fastening hole 110a of the main part 110 and the fastening hole 58a of the bump 58. In other embodiments, the step of fixing the main part 110 to the first structure component 52 can also include gluing the main part 110 to the first structure component 52, and the fixing method is not limited herein.

The assembling method of the embodiment further includes a step of detaching the buckled first structure component 52 from the second structure component 54. First, an external force is applied onto one of the first structure component 52 and the second structure component 54 so as to break the hook part 120 of the assembling element 100 and separate the buckled first structure component 52 from the second structure component 54. Next, the damaged assembling element 100 is removed and another assembling element is installed so that the first structure component 52 can be locked to the second structure component 54 firmly again. With the above-mentioned design, when detaching the first structure component 52 from the second structure component 54, the hook part 120 of the assembling element 100 will definitely be broken so whether the electronic device has ever been dissembled can be determined accordingly.

In summary, the assembling element of the invention is fixed to the first structure component so that the first structure component can be locked to the second structure component firmly through the hook part of the main part. Accordingly, the first structure component can be assembled with the second structure component without screws. Therefore, users are enabled to quickly assemble or dissemble the first structure component 52, and thus the electronic devices 50 can be maintained and dissembled more conveniently. In addition, the assembling element can be fixed to an inner surface of the first structure component and hidden within the electronic device, to provide the electronic device with better appearance.

It will be apparent to those skilled in the art that the descriptions above are several preferred embodiments of the present invention only, which does not limit the implementing range of the present invention. Various modifications and variations can be made to the structure of the present invention without departing from the scope or spirit of the present invention. The claim scope of the present invention is defined by the claims hereinafter.

What is claimed is:

1. A replaceable assembling element for fixing structures, suitable for an electronic device, wherein the electronic device has a first structure component and a second structure component, the assembling element comprises:
a main part, fixed to the first structure component; and
a hook part, connected to the main part, wherein the hook part is buckled to the second structure component so as to lock the first structure component to the second structure component firmly.

2. The assembling element as claimed in claim 1, wherein
the main part comprises a fastening hole,
the electronic device further comprises a fastening element, and
the fastening element fastens the main part to the first structure component through the fastening hole.

3. The assembling element as claimed in claim 1, wherein the hook part is integrally connected to the main part.

4. The assembling element as claimed in claim 1, wherein
the main part comprises a recess,
the electronic device further comprises a bump, and
the bump is fixed to the first structure component and inserted into the recess of the main part.

5. The assembling element as claimed in claim 4, wherein
the main part comprises a first fastening hole and the bump comprises a second fastening hole,
the electronic device further comprises a fastening element, and
the fastening element fastens the main part to the first structure component through the first fastening hole and the second fastening hole.

6. The assembling element as claimed in claim 1, wherein the main part is glued to the first structure component.

7. The assembling element as claimed in claim 1, wherein the assembling element is fixed to an inner surface of the first structure component and hidden within the electronic device.

8. The assembling element as claimed in claim 1, wherein the assembling element is made of plastic.

9. An assembling method for structure components of electronic device, wherein the electronic device comprises a first structure component and a second structure component, the assembling method comprises:
providing an assembling element, wherein the assembling element comprises a main part and a hook part, and the hook part is connected to the main part;
fixing the main part to the first structure component; and
applying an external force onto the first structure component or the second structure component so as to buckle the hook part of the first structure component to the second structure component.

10. The assembling method as claimed in claim 9, further comprising a step of detaching the buckled first structure component from the second structure component, the step comprises:
applying an external force onto one of the first structure component and the second structure component so as to break the hook part of the assembling element to separate the buckled first structure component from the second structure component; and
removing the damaged assembling element and installing another assembling element.

11. The assembling method as claimed in claim 9, wherein
the main part comprises a fastening hole, and
the step of fixing the main part to the first structure component comprises:
providing a fastening element; and
fastening, by the fastening element, the main part to the first structure component through the fastening hole.

12. The assembling method as claimed in claim 9, wherein
the main part comprises a recess,
the electronic device comprises a bump,
the bump is fixed to the first structure component, and
the step of fixing the main part to the first structure component comprises:
inserting the bump into the recess of the main part.

13. The assembling method as claimed in claim 12, wherein
the main part comprises a first fastening hole,
the bump comprises a second fastening hole, and
the step of fixing the main part to the first structure component comprises:
providing a fastening element; and
fastening, by the fastening element, the main part to the first structure component through the first fastening hole and the second fastening hole.

14. The assembling method as claimed in claim 9, wherein the step of fixing the main part to the first structure component comprises:
gluing the main part to the first structure component.

15. The assembling method as claimed in claim 9, wherein the method of fastening the first structure component to the second structure component is screwless buckling.
